(19) United States
(12) Patent Application Publication
(10) Pub. No.: US 2014/0084070 A1
(43) Pub. Date: Mar. 27, 2014

(54) CHIP CARD AND METHOD FOR MANUFACTURING A CHIP CARD

(71) Applicant: INFINEON TECHNOLOGIES AG, Neubiberg (DE)

(72) Inventors: Frank Pueschner, Kelheim (DE); Siegfried Hoffner, Nesselwang (DE); Peter Stampka, Burglengenfeld (DE); Wolfgang Schindler, Regenstauf (DE); Stephan Rampetzreiter, Graz (AT)

(73) Assignee: INFINEON TECHNOLOGIES AG, Neubiberg (DE)

(21) Appl. No.: 13/625,888

(22) Filed: Sep. 25, 2012

(51) Int. Cl. G06K 19/02; H05K 13/00; G06K 19/077

(52) U.S. Cl. 235/492; 29/601

(57) ABSTRACT

According to one embodiment, a chip card is provided comprising a booster antenna wherein the booster antenna comprises a material having an electrical resistivity of at least 0.05 Ohm*mm²/m.

### TECHNICAL FIELD

The present disclosure relates to chip cards and methods for manufacturing a chip card.

### BACKGROUND

The communication between chip cards which are for example used for electronic payment may be carried out via a contact based interface, i.e. by means of exposed chip card contacts. For this, however, the user has to insert the ship card into the reader which may be annoying to the user. This can be avoided by using so-called dual interface chip cards which can communicate with a reader via a contactless interface in addition to the contact based interface. The contactless interface may include a chip card antenna, which is included in the chip card and which is connected to a chip of the chip card. The chip and the chip card antenna may both be arranged on a chip card module. In this case, the chip card antenna may be referred to as chip card module antenna.

In electronic payment systems, it is typically required that a communication can take place when the distance between the chip card and the reader is 4 cm (or less). The area which is available on the chip card module may not be sufficient to include a chip card module antenna of sufficient size to allow a communication in this distance. To improve the communication capabilities, a further antenna, denoted as booster antenna, may be included. The booster antenna may be included in a separate layer and may be included in the chip card.

It is desirable to provide chip cards with booster antennas such that requirements according to performance standards such as the EMV standard or ISO/IEC 10373-6 are fulfilled.

### SUMMARY

According to one embodiment, a chip card is provided including a booster antenna wherein the booster antenna includes a material having an electrical resistivity of at least 0.05 Ohm*mm²/m.

According to another embodiment, a method for manufacturing a chip card is provided including forming a booster antenna on the chip card from a material having an electrical resistivity of at least 0.05 Ohm*mm²/m.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects are described with reference to the following drawings, in which:

FIG. 1 shows a section of the back side of a chip card module with a chip card module antenna which may be used with a booster antenna.

FIG. 2 shows a communication arrangement including a reader and a chip card 201.

FIG. 3 shows a voltage diagram.

FIG. 4 shows a chip card according to an embodiment.

FIG. 5 shows a chip card according to an embodiment.

FIG. 6 shows a flow diagram.

### DESCRIPTION

The following detailed description refers to the accompanying drawings that show, by way of illustration, specific details and aspects of this disclosure in which the invention may be practiced. These aspects of this disclosure are described in sufficient detail to enable those skilled in the art to practice the invention. Other aspects of this disclosure may be utilized and structural, logical, and electrical changes may be made without departing from the scope of the invention. The various aspects of this disclosure are not necessarily mutually exclusive, as some aspects of this disclosure can be combined with one or more other aspects of this disclosure to form new aspects.

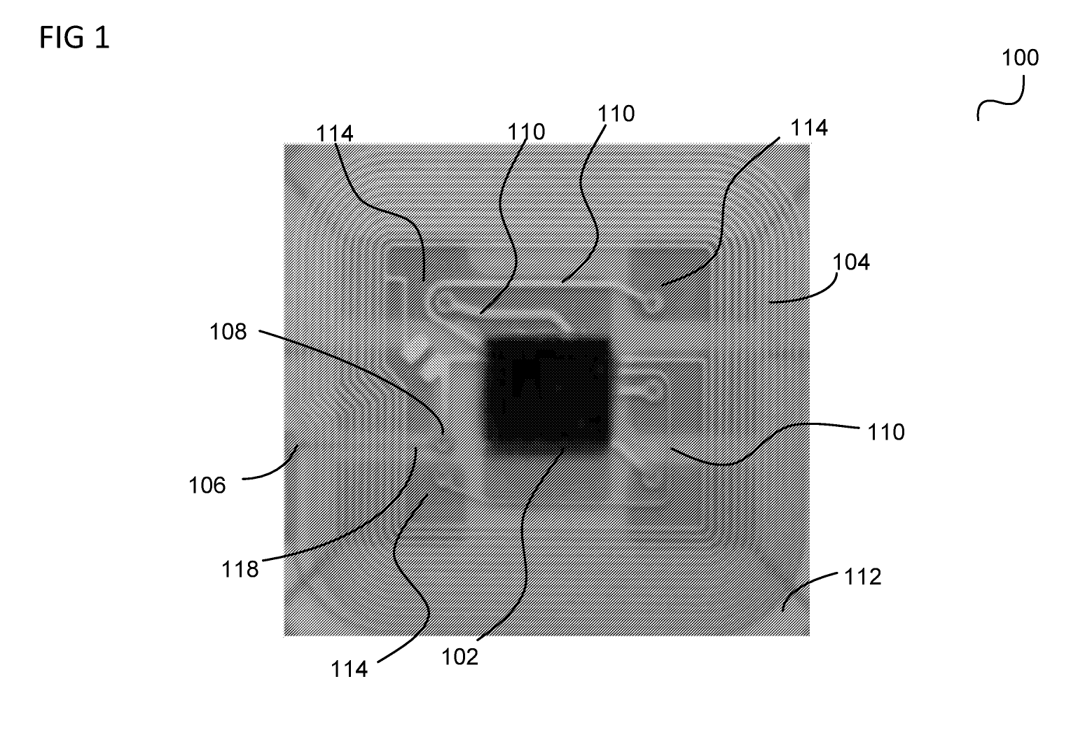

FIG. 1 shows a section of the back side of a chip card module 100 with a chip card module antenna which may be used (e.g. by means of inductive coupling) with a booster antenna.

The back side of the chip card module 100 can be seen to refer to the side which is opposite to the side on which the chip card contacts are arranged and which is not visible from the outside after inserting the chip card module into the chip card body.

The chip card module 100 includes a carrier 112 on which a chip 102 is arranged. As shown in FIG. 1, the carrier 112 may be at least partially transparent such that the chip card contacts 114 which are arranged on the front side of the carrier 112 are visible from the back side of the chip card module 100. The chip card contacts 114 are coupled my means of a wiring 110 with the chip 102.

A chip-external coil 104 is provided on the back side of the carrier 112 which in this example includes 13 windings. The windings are arranged around the chip 102. The coil includes an end terminal 104 at its end which is connected, by means of a via, with a contact bridge 118 on the front side of the carrier. The contact bridge 118 is connected by means of a further via with a further contact 108 which is coupled to the chip 102.

The coil 104 forms a chip card module antenna which is closed by the contact bridge 118. The chip 102 arranged on the carrier 112 can for example have an inner capacity of 40 pF to 100 pF, for example in the range of about 50 pF to 80 pF. The windings of the coil 104 can for example include silver, aluminum, copper, gold and/or conductive allows and can have a width of at least 40 μm, e.g. about 60 μm, about 80 μm, about 100 μm or about up to 200 μm. The windings of the coil 104 may for example be arranged in a distance of about 80 μm with respect to each other on the carrier 112. The width of the windings and the distance between the windings may be adjusted in view of the desired inductivity of the coil 104.

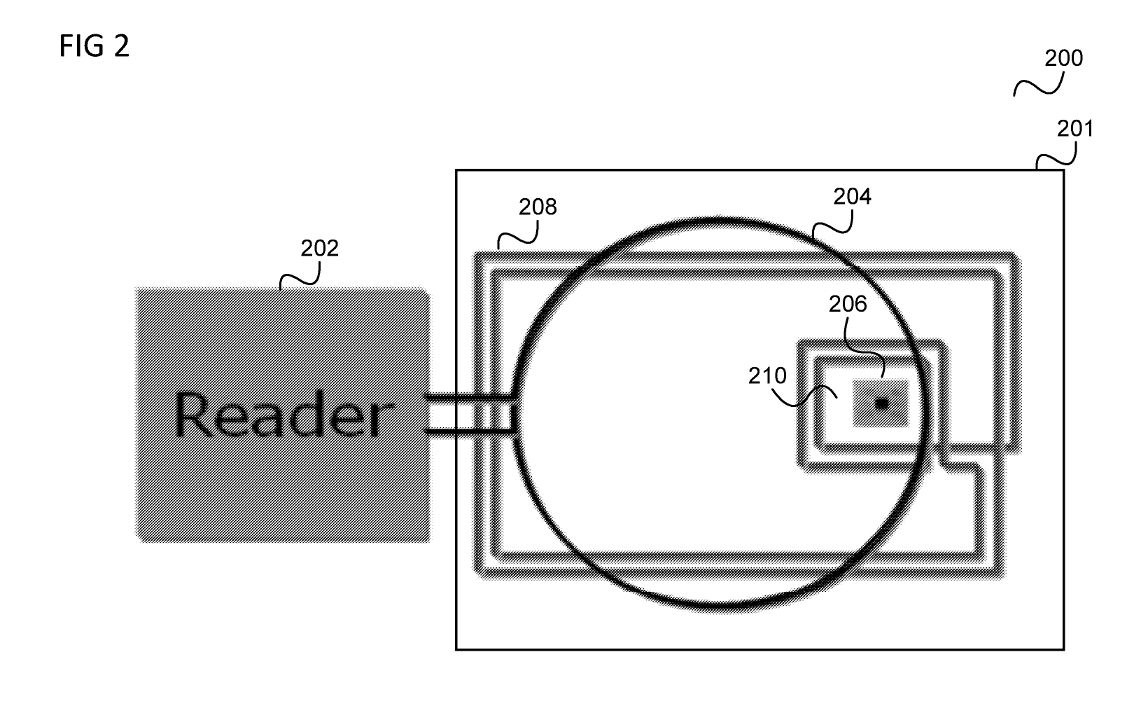

The chip card module 100 in this example is a so called coil on module which includes the chip card chip and a coil having the function of a chip card antenna allowing the contact less communication between the chip and a reader. The chip card module 100 may be a dual interface chip card module such that the chip 102 may communicate via a contact based interface (by means of the contacts 114) as well as by means of a contact less interface (by means of the coil 104) with a reader. To improve the communication capabilities of a chip card including the chip card module 100, a booster antenna may be provided on the chip card. This is illustrated in FIG. 2.

FIG. 2 shows a communication arrangement 200 including a reader 202 and a chip card 201. The reader includes an antenna 204 which is for example arranged in a housing onto which the chip card 201 is placed. The chip card 201 includes a chip card module 206, for example corresponding to the chip card module 100 and a booster antenna 208.

The booster antenna 208 can be seen to act as an amplifier between the antenna 204 of the reader and the chip card module antenna of the chip card module 206. The booster antenna 208 has larger windings than the chip card module antenna and can therefore better couple with the magnet field emitting from the antenna 204 of the reader 202. The booster antenna 208 is coupled by at least one inductive coupling region 210 with the chip card module antenna of the chip card module 206.

The inductive coupling region 210 may for example be enclosed by coupling windings which surround the chip card module 206 and thus the chip card module antenna.

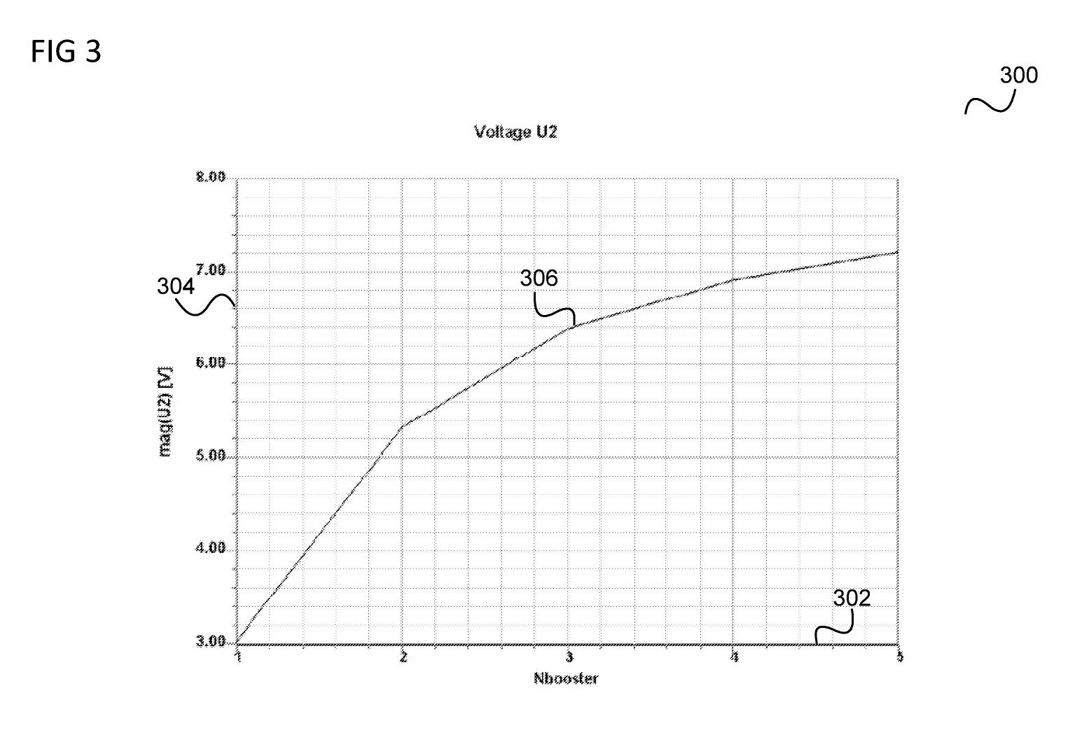

The effect of a booster antenna on the chip card module antenna or the voltage induced in the chip card module 206 by the electromagnetic field emitted by the reader antenna 204 is illustrated in FIG. 3.

FIG. 3 shows a voltage diagram 300.

In the diagram 300, the number of windings of the booster antenna increases along the x-axis 302. The number of windings can refer to the windings which are larger than the (optional) coupling windings enclose the coupling region 210. In the example shown in FIG. 2, the booster antenna 208 has two windings and the coupling region 210 is enclosed by two coupling windings. These winding numbers may be higher or lower which effects the power received by the chip card from the reader.

Along the y-axis 304, the voltage that is induced in the chip card module by the electromagnetic field emitted by the antenna 204 increases.

The graph 306 illustrates that the induced voltage increases when the number of windings increases. The increase in voltage per additional winding decreases which can be seen from the decreasing gradient of the graph 306 for a higher number of windings.

The number of windings of the booster antenna 208 may be limited by the area available on the chip card. In principle, the booster antenna 208 can extend via an area limited by the size of the chip card 201. The booster antenna can be arranged within a layer of the chip card 201.

Electrical requirements for chip cards are for example given by the ISO/IEC 14443 standard, the ISO/IEC 10373-6 standard and the EMVCo standard (EMV standard for contact less chip cards), e.g. the EMV Contactless Communication Protocol Specification version 2.0.1. An important requirement is the minimal operating field strength, i.e. the minimal field strength, at which a signal transmission between the chip card 201 and the reader 202 may take place. Further, the minimum load modulation amplitude (LMA) is of importance. This parameter describes the magnetic field amplitude which can be achieved by load modulation which can cause a change of the magnetic field of the reader 202 within the typical operation range. Another important aspect is the maximum loading effect which is related to the retroaction of the chip card 201 on the reader 202. The chip card is operated by the electromagnetic field of the reader 202 and itself generates an electromagnetic field which retroacts on the reader 202. The maximum retroaction defines a limit for this retroaction effect such that the reader can operate correctly.

Further requirements for the booster antenna 208 are related to its mechanical characteristics. For example, booster antennas 208 typically need to be embeddable within a chip card such that the size of the chip card gives rise to a limit of the size of the booster antenna. Further, the design and the shape of the booster antenna 208 may subject to constraints arising for example from areas of the chip card 201 which need to stay empty of the booster antenna, for example areas used for embossing such as defined in the ISO/IEC 7810-11 standard.

According to the requirements described above, it may for example be desirable to provide a booster antenna for a chip card such that the maximum loading effect is reduced under a certain limit, as for example given by the ISO/IEC 10373-6 norm or the EMV Contactless Communication Protocol Specification version 2.0.1, without increasing the minimum operating field strength of the chip card. The maximum loading effect can for example be reduced by reducing the quality factor of the booster antenna 208 which is given by the product of the operating frequency and the inductivity of the booster antenna 208 divided by the resistance of the booster antenna 208. The quality factor further plays a role in the optimization of the power transfer. The quality factor can be reduced by increasing the resistance of the booster antenna 208.

It may be further desirable to manufacture booster antennas economically while fulfilling the requirements (such as the electrical requirements) described above.

The booster antenna 208 may for example be economically manufactured by using wired technology, in which conductive structures made of a wire are arranged on a substrate surface or a carrier surface. The manufacturing of the booster antenna 208 may for example be especially economical when the following is fulfilled:
wire length ≦2.5 m. This allows low process cycle times and thus low costs.
wire diameter ≧60 μm. This allows high processing stability (reduced danger of wire ripping) and low process cycle times and thus low costs.
breaking strength ≧200N/mm². This allows high processing stability (reduced danger of wire ripping) and low process cycle times and thus low costs.
reduction of the quality factor by increasing the resistance of the booster antenna 208.

According to one embodiment, the above requirements for the usage of the wired technology a material (e.g. a wire alloy) is used for the booster antenna 208 which has a sufficient resistivity (in other words specific resistance) to fulfill the requirement of an increased resistance of the booster antenna 208 (to reduce the quality factor) while being within the limits regarding the wire diameter and the wire length and having a certain breaking strength since these factors have an immediate impact on the manufacturing costs.

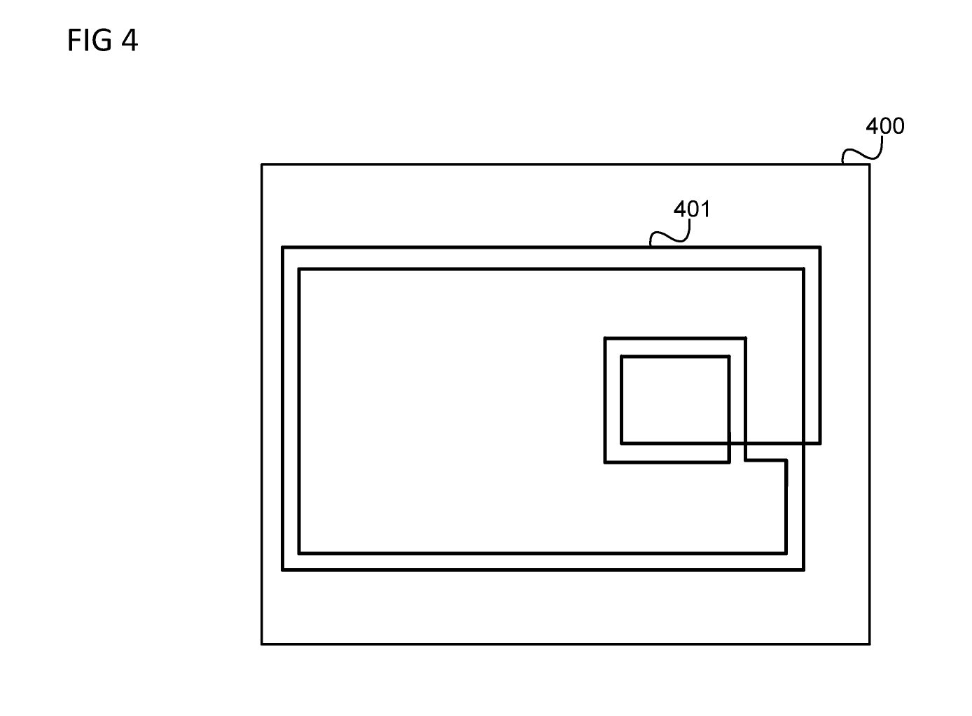

FIG. 4 shows a chip card 400 according to an embodiment.

The chip card 400 includes a booster antenna 401 wherein the booster antenna includes a material having an electrical resistivity of at least 0.05 Ohm*mm²/m.

In other words, according to one embodiment, a material is used for the booster antenna which has a resistivity that is so high that the diameter of the wire forming the booster antenna may be chosen sufficiently high to allow easy manufacturing while still having a booster antenna with sufficiently high resistance such that the resulting quality factor is low.

A booster antenna may be understood as an antenna arranged on the chip card which is provided in addition to a chip card module antenna, i.e. an antenna that is part of the chip card module, e.g. a chip-external antenna. The booster antenna is for example inductively coupled to the chip card module antenna. The booster antenna can be understood as an amplification antenna which amplifies the power received by the chip card from the reader (i.e. the electromagnetic power emitted by the reader). The booster antenna is for example an antenna with larger windings than the chip card module antenna and for example surrounds the chip card module antenna. The chip card may for example have a contact less interface which may be formed by the booster antenna (among other components).

The chip card is for example a chip card in accordance with the ISO/IEC 7810 standard. The chip card may have any of the usual formats ID-1, ID-2, ID-3, ID-000 or 3FF. Depending on the size of the chip card, two chip card modules may be arranged on the chip card such that the chip card may be inserted with one of its ends into a reader such that the user can choose which chip card module should be used. In this case, a chip card module antenna may be arranged in a separate inductive coupling section of the chip card.

The material for example has an electrical resistivity of at least 0.15 Ohm*mm²/m.

For example, the material has an electrical resistivity between 0.15 Ohm*mm²/m and 0.3 Ohm*mm²/m.

In one embodiment, the material has an electrical resistivity between 0.15 Ohm*mm²/m and 0.2 Ohm*mm²/m.

The material is for example at least one of a copper nickel alloy (CuNi), a copper tin alloy (CuSn), a copper zinc alloy (CuZn), an iron chromium alloy (i.e. stainless steel), an aluminum magnesium alloy (AlMg), or nickel (Ni).

These materials may each have a resistivity in the range of 0.05 Ohm*mm²/m to 1 Ohm*mm²/m and a breaking strength of ≧200 N/mm²

In one embodiment, the material is an alloy.

For example, the material is a copper alloy.

The material is for example CuNi10, CuSn6, CuNi6, or CuNi23Mn.

The material (and thus the booster antenna) has for example a breaking strength of at least 200 N/mm²

The booster antenna consists of the material. In other words, the booster antenna may be made of the material. This may apply to all the examples of the material given above and below.

The booster antenna has for example a length of at most 2.5 m.

The booster antenna for example has a diameter of at least 60 μm.

The chip card may further including a chip card module including a chip card module antenna.

The chip card module antenna is for example inductively coupled to the booster antenna.

The chip card is for example a dual interface chip card.

It should be noted that for all of the given values, variations may be possible such that a statement of a parameter being equal, lower or higher to/than the value may be understood as the parameter being equal, lower or higher, respectively to/than about that value.

For example, the booster antenna is formed of an alloy CuNi10 (wherein the “10” indicates 10 percent nickel; a similar denotation is used herein for other alloys) which has a resistivity of 0.15 Ohm*mm²/m with a wire diameter of 80 μm, a breaking strength within 320 to 308 N/mm² and a wire length of 1.67 m.

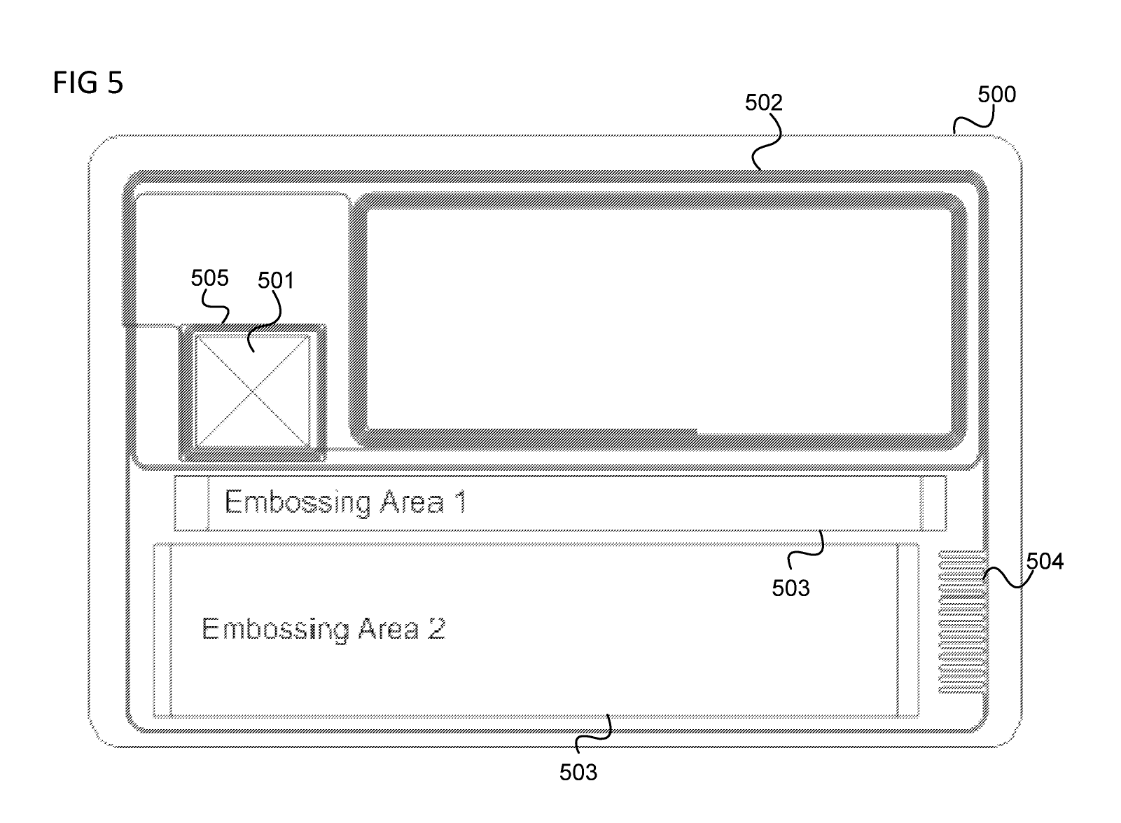

An example of a chip card is shown in FIG. 5.

FIG. 5 shows a chip card 500 according to an embodiment.

The chip card 500 includes a chip card module 501, a booster antenna 502 and two embossing areas 503. The booster antenna includes coupling windings 504 which surround the chip card module 501 and are provided for inductive coupling between the booster antenna 502 and a chip card module antenna of the chip card module 501.

Optionally, the booster antenna 502 may be coupled with an additional conductive structure 505, e.g. including a resistance, which may for example be used to increase the resistance of the resulting arrangement of booster antenna 502 and additional conductive structure 505 compared to the booster antenna 502 without the additional conductive structure 505. It should be noted that by forming the booster antenna 502 from one of the above-mentioned materials such as CuNi, CuSn, CuZn, stainless steel, AlMg or Ni as above, the additional conductive structure 505 may not be necessary and may be omitted.

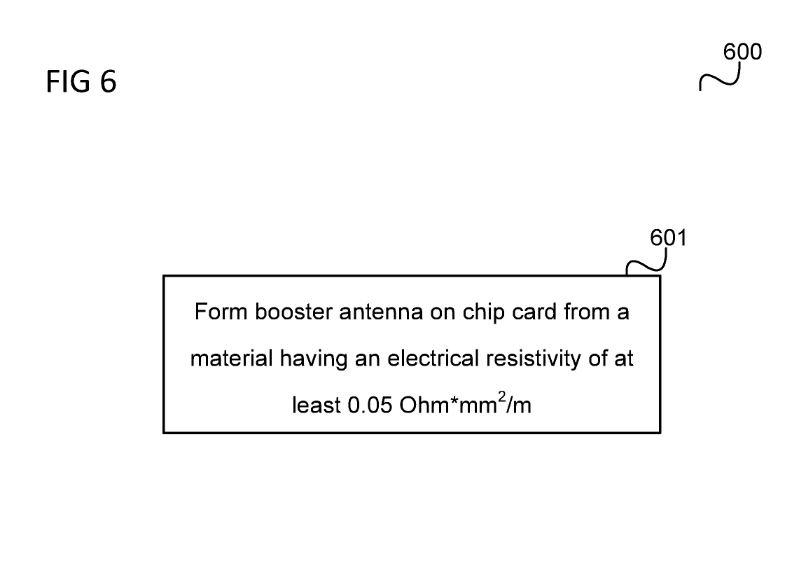

A method for forming a chip card is illustrated in FIG. 6.

FIG. 6 shows a flow diagram 600.

In 601, a booster antenna is formed on the chip card from a material having an electrical resistivity of at least 0.05 Ohm*mm²/m.

The booster antenna is for example formed from the material by means of wired technology.

For example, the booster antenna is formed such that the booster antenna includes the material.

In one embodiment, the booster antenna is formed such that the booster antenna consists of the material.

It should be noted that embodiments described in context of the method illustrated in FIG. 6 are analogously valid for the chip card 200 and vice versa.

While specific aspects have been described, it should be understood by those skilled in the art that various changes in form and detail may be made therein without departing from the spirit and scope of the aspects of this disclosure as defined by the appended claims. The scope is thus indicated by the appended claims and all changes which come within the meaning and range of equivalency of the claims are therefore intended to be embraced.

1. A chip card comprising
a booster antenna wherein the booster antenna comprises a material having an electrical resistivity of at least 0.05 Ohm*mm²/m and a breaking strength of at least 270 N/mm².

2. The chip card according to claim 1, wherein the material has an electrical resistivity of at least 0.15 Ohm*mm²/m.

3. The chip card according to claim 1, wherein the material has an electrical resistivity between 0.15 Ohm*mm²/m and 0.3 Ohm*mm²/m.

4. The chip card according to claim 1, wherein the material has an electrical resistivity between 0.15 Ohm*mm²/rn and 0.2 Ohm*mm²/m.

5. The chip card according to claim 1, wherein the material is at least one of a copper nickel alloy, a copper tin alloy, a copper zinc alloy, an iron chromium alloy, an aluminum magnesium alloy, or nickel.

6. The chip card according to claim 1, wherein the material is an alloy.

7. The chip card according to claim 1, wherein the material is a copper alloy.

8. The chip card according to claim 1, wherein the material is CuNi10, CuSn6, CuNi6, or CuNi23Mn.

9. (canceled)

10. The chip card according to claim 1, wherein the booster antenna consists of the material.

11. The chip card according to claim 1, wherein the booster antenna has a length of at most 2.5 m.

12. The chip card according to claim 1, wherein the booster antenna has a diameter of at least 60 μm.

13. The chip card according to claim 1, further comprising a chip card module including a chip card module antenna.

14. The chip card according to claim 1, wherein the chip card module antenna is inductively coupled to the booster antenna.

15. The chip card according to claim 1, wherein the chip card is a dual interface chip card.

16. Method for manufacturing a chip card comprising forming a booster antenna on the chip card from a material having an electrical resistivity of at least 0.05 Ohm*mm²/m and a breaking strength of at least 270 N/mm².

17. Method according to claim 16, comprising
forming the booster antenna from the material by means of wired technology.

18. Method according to claim 16, comprising
forming the booster antenna such that the booster antenna comprises the material.

19. Method according to claim 16, comprising
forming the booster antenna such that the booster antenna consists of the material.

20. The chip card according to claim 1, wherein the material has a breaking strength of at least 280 N/mm².

21. The chip card according to claim 1, wherein the material has a breaking strength of at least 290 N/mm².

22. The chip card according to claim 1, wherein the material has a breaking strength of at least 300 N/mm².

23. A chip card comprising
a booster antenna wherein the booster antenna comprises a material having an a breaking strength of at least 270 N/mm².

24. The chip card according to claim 23, wherein the material has a breaking strength of at least 280 N/mm².

25. The chip card according to claim 23, wherein the material has a breaking strength of at least 290 N/mm².

26. The chip card according to claim 23, wherein the material has a breaking strength of at least 300 N/mm².
